(19) United States
(12) Patent Application Publication
(10) Pub. No.: US 2026/0371756 A1
(43) Pub. Date: Nov. 19, 2026

(54) Image Sensor with a Hybrid Photodiode Structure

(71) Applicant: SAMSUNG ELECTRONICS CO., LTD, Suwon-si (KR)

(72) Inventors: Sung-Yool CHOI, Daejeon-si (KR); Seung Hun HAN, Daejeon-si (KR); Cheolmin PARK, Daejeon-si (KR); Hyeok Jun JIN, Daejeon-si (KR)

(73) Assignees: SAMSUNG ELECTRONICS CO., LTD., Suwon-si (KR); KOREA ADVANCED INSTITUTE OF SCIENCE AND TECHNOLOGY, Daejeon (KR)

(21) Appl. No.: 18/611,828

(22) Filed: Mar. 21, 2024

(30) Foreign Application Priority Data
Mar. 24, 2023 (KR) 10-2023-0039266
Jun. 2, 2023 (KR) 10-2023-0071849

(51) Int. Cl. H10F 39/00; H10F 39/18

(52) U.S. Cl. CPC H10F 39/8033; H10F 39/014; H10F 39/18; H10F 39/806; H10F 39/807

(57) ABSTRACT

Provided is an image sensor including a semiconductor substrate, a two-dimensional material layer on an upper surface of the semiconductor substrate and including molybdenum disulfide (MoS₂), and a top absorber on an upper surface of the two-dimensional material layer and including graphene, and a plurality of plasmon nanoparticles on an upper surface of the top absorber, wherein the semiconductor substrate includes silicon doped with p-type impurities and the two-dimensional material layer has an n-type conductivity, the two-dimensional material layer and the semiconductor substrate forming a pn diode.

### CROSS-REFERENCE TO RELATED APPLICATION

This application claims priority to Korean Patent Application Nos. 10-2023-0039266, filed on Mar. 24, 2023, and 10-2023-0071849, filed on Jun. 2, 2023, in the Korean Intellectual Property Office, the disclosures of which are incorporated by reference herein in their entireties.

### BACKGROUND

Embodiments of the present disclosure relate to an image sensor. More specifically, embodiments of the present disclosure relate to an image sensor including a photodiode having a hybrid structure including a two-dimensional material and a three-dimensional material.

An image sensor is a device that converts an optical image signal into an electrical signal. The image sensor includes a plurality of pixels, and each pixel includes a photodiode area that receives incident light and converts the incident light into the electrical signal. As the integration degree of the image sensor has been increased, the size of each pixel has been decreased, and thus, there is a problem in that the image quality has decreased, especially in a low-light environment.

### SUMMARY

According to an aspect of an embodiment, there is provided an image sensor including a semiconductor substrate, a two-dimensional material layer on an upper surface of the semiconductor substrate and including molybdenum disulfide (MoS₂), and a top absorber on an upper surface of the two-dimensional material layer and including graphene, and a plurality of plasmon nanoparticles on an upper surface of the top absorber, wherein the semiconductor substrate includes silicon doped with p-type impurities and the two-dimensional material layer has an n-type conductivity, the two-dimensional material layer and the semiconductor substrate forming a pn diode.

According to another aspect of an embodiment, there is provided an image sensor including a semiconductor substrate, a two-dimensional material layer on an upper surface of the semiconductor substrate and including molybdenum disulfide (MoS2), the two-dimensional material layer including two to five two-dimensional sheets on the upper surface of the semiconductor substrate in a vertical direction, and a top absorber on an upper surface of the two-dimensional material layer and including a monolayer of graphene, wherein a plurality of plasmon nanoparticles are on an upper surface of the top absorber.

According to another aspect of an embodiment, there is provided an image sensor including a semiconductor substrate including a doped region doped with p-type impurities, a two-dimensional material layer on an upper surface of the semiconductor substrate and including molybdenum disulfide (MoS2), the two-dimensional material layer including two to five two-dimensional sheets on the upper surface of the semiconductor substrate in a vertical direction, a top absorber on an upper surface of the two-dimensional material layer and a monolayer of graphene, a first electrode on the top absorber, and a second electrode on a lower surface of the semiconductor substrate and electrically connected to the doped region, wherein a plurality of plasmon nanoparticles are on an upper surface of the top absorber, and wherein each of the plurality of plasmon nanoparticles contacts the monolayer of graphene of the top absorber based on a plasmon bonding.

### BRIEF DESCRIPTION OF DRAWINGS

Embodiments will be more clearly understood from the following detailed description taken in conjunction with the accompanying drawings in which:

FIG. 1 is a perspective view schematically illustrating an image sensor according to embodiments;

FIG. 2 is a cross-sectional view of the image sensor in FIG. 1;

FIG. 3 is a schematic view illustrating a schematic energy band structure of an image sensor according to embodiments;

FIG. 4 is a graph showing a voltage-current characteristic of an image sensor according to embodiments;

FIGS. 5A and 5B are graphs showing a voltage-optical current characteristic of an image sensor according to embodiments;

FIG. 6 is a graph showing responsivity according to power of incident light of an image sensor according to embodiments;

FIG. 7 is a graph showing responsivity and quantum efficiency according to wavelength of incident light of an image sensor according to embodiments;

FIG. 8 is a graph showing an absorption degree of incident light according to a type of plasmon nanoparticles in the image sensor according to embodiments;

FIGS. 9A and 9B are graphs showing an absorption degree of incident light according to a diameter of nanoparticles and a separation distance between nanoparticles in the image sensor according to embodiments;

FIGS. 10, 11, and 12 are cross-sectional views illustrating a method of manufacturing an image sensor according to embodiments; and

FIG. 13 is a block diagram showing a configuration of an image sensor according to embodiments.

### DETAILED DESCRIPTION OF EMBODIMENTS

Hereinafter, embodiments are described in detail with reference to the accompanying drawings. The same reference numerals denote the same elements in the drawings, and redundant descriptions on the same elements are omitted.

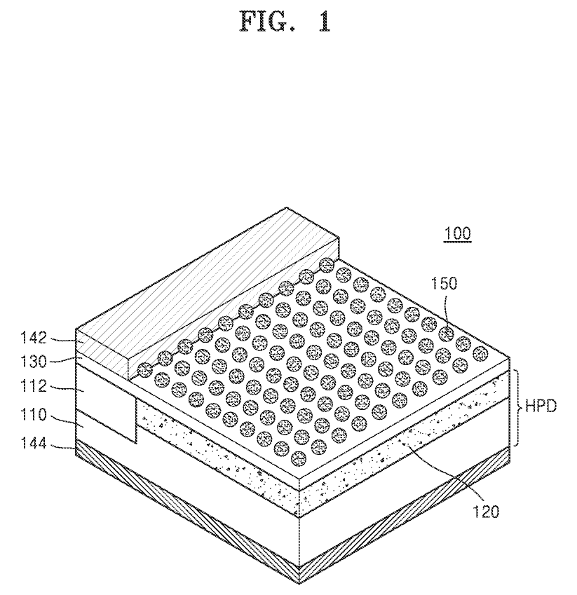

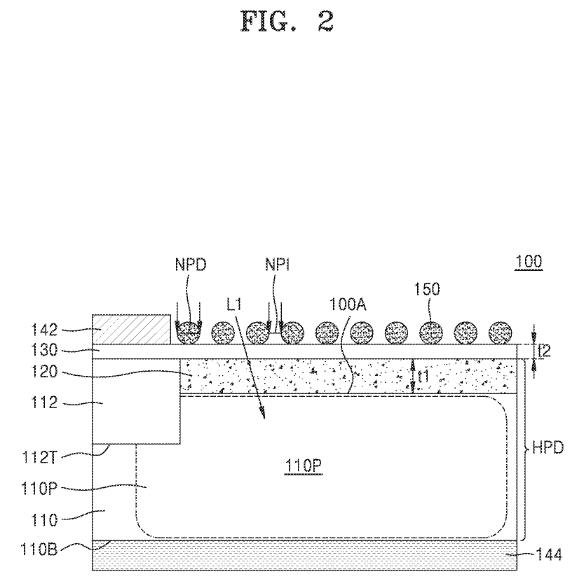

FIG. 1 is a perspective view schematically illustrating an image sensor 100 according to embodiments. FIG. 2 is a cross-sectional view of the image sensor 100 in FIG. 1.

Referring to FIGS. 1 and 2, the image sensor 100 may include a semiconductor substrate 110, a two-dimensional material layer 120, a top absorber 130, a first electrode 142, a second electrode 144, and a plurality of plasmon nanoparticles 150.

The semiconductor substrate 110 may include a silicon substrate doped with p-type impurities. The semiconductor substrate 110 may include an upper surface 110A and a lower surface 110B opposite to each other. The semiconductor substrate 110 may include a plurality of pixel regions on which light L1 is incident from the outside of the image sensor 100.

A doped region 110P doped with p-type impurities may be arranged in the semiconductor substrate 110. The doped region 110P may be formed by injecting, for example, boron (B) or gallium (Ga) ions into the semiconductor substrate 110. The doped region 110P may constitute a portion of the hybrid photodiode HPD.

The two-dimensional material layer 120 may be arranged on the top surface 110A of the semiconductor substrate 110. In some embodiments, the two-dimensional material layer 120 may have a two-dimensional layered structure. In some embodiments, the two-dimensional material layer 120 may include transition metal dichalcogenides. In some embodiments, the transition metal dichalcogenide may include at least one transition metal element selected from the group consisting of molybdenum (Mo), tungsten (W), and platinum (Pt), and at least one chalcogen element selected from the group consisting of sulfur (S), selenium (Se), and tellurium (Te). For example, the two-dimensional material layer 120 may include molybdenum disulfide (MoS₂) as a transition metal dichalcogenide. In some embodiments, the two-dimensional material layer 120 may have an n-type conductivity.

In some embodiments, the two-dimensional material layer 120 may be composed of two-dimensional sheets of two to five layers. The two-dimensional sheet of one layer may have a structure in which a plurality of unit cells are repeatedly arranged two-dimensionally (e.g., on an x-y plane) and a molybdenum atomic layer of one layer is positioned, as a sandwich structure, between a sulfur atomic layer positioned on the molybdenum atomic layer and another sulfur atomic layer positioned under the molybdenum atomic layer. For example, in the unit cell, the two-dimensional sheet of one layer may include a bonding structure in which a single molybdenum atom is bonded to three sulfur atoms thereon and three sulfur atoms thereunder in covalent bonds.

In some embodiments, since the two-dimensional material layer 120 is composed of two-dimensional sheets of two to five layers, the two-dimensional material layer 120 may have a first thickness t1 of about 1.5 nm to about 3.5 nm. In some embodiments, the two-dimensional material layer 120 may be conformally formed on the upper surface 110A of the semiconductor substrate 110 by a chemical vapor deposition process, and be formed to have a relatively large area to cover the entire upper surface of the doped region 110P.

The two-dimensional material layer 120 may constitute a two-dimensional/three-dimensional hybrid photodiode HPD together with the doped region 110P of the three-dimensional bulk semiconductor substrate 110 thereunder. For example, since the doped region 110P of the semiconductor substrate 110 has a p-type conductivity and the two-dimensional material layer 120 has an n-type conductivity, the two-dimensional material layer 120 and the doped region 110P of the semiconductor substrate 110 may constitute a pn diode. As the two-dimensional material layer 120 has a first thickness t1, which is relatively small, and is arranged two-dimensionally, a relatively narrow depletion region, which extends two-dimensionally, may be provided between the two-dimensional material layer 120 and the doped region 110P of the semiconductor substrate 110.

The top absorber 130 may be arranged on the two-dimensional material layer 120. The top absorber 130 may include graphene. In some embodiments, the top absorber 130 may include a monolayer of graphene. In some embodiments, the top absorber 130 may be arranged to cover an entire upper surface of the two-dimensional material layer 120. When the top absorber 130 includes a monolayer of graphene, the top absorber 130 may have a second thickness t2 of about 0.1 nm to about 1 nm.

When electron-hole pairs are excited by light that is formed in the two-dimensional material layer 120 and the doped region 110P, the top absorber 130 may quickly absorb the electrons and transfer the electrons to the first electrode 142, so that the top absorber 130 may function as a carrier absorbing layer. In addition, the top absorber 130 may function as an electron-hole pair amplification member depending on characteristic energy band properties. In that case, a strong electric field may need to be applied in graphene for multiple carriers generated in graphene to be separated in a relatively short time and collected into electrodes prior to being recombined. In this regard, a relatively strong electric field caused by a reverse voltage applied between the two-dimensional material layer 120 and the doped region 110P may extend to graphene, to thereby enable the multiple carriers in graphene to be more effectively collected.

The top absorber 130 is described to include the monolayer of graphene but is not limited thereto, and the top absorber 130 may include two or more two-dimensional graphene sheets as long as the top absorber 130 functions as the carrier absorbing layer and an electron-hole pair amplifier.

A device isolation trench 112T may be formed on the semiconductor substrate 110, and a device isolation layer 112 may be arranged on inner walls of the device isolation trench 112T. The device isolation layer 112 may include an insulating material such as, for example, silicon oxide. The device isolation trench 112T may be formed to penetrate a portion of the two-dimensional material layer 120, and accordingly, the two-dimensional material layer 120 may not be positioned on an upper surface of the device isolation layer 112. However, the disclosure is not limited thereto, and in other embodiments, the two-dimensional material layer 120 may extend onto the upper surface of the device isolation layer 112.

The top absorber 130 may extend onto the upper surface of the device isolation layer 112, and the first electrode 142 may be arranged on the top absorber 130 that is arranged on the device isolation layer 112. The first electrode 142 may be electrically connected to the top absorber 130. In some embodiments, the first electrode 142 may include at least one of chromium (Cr), gold (Au), aluminum (Al), cobalt (Co), copper (Cu), and nickel (Ni).

The second electrode 144 may be arranged on the lower surface 110B of the semiconductor substrate 110. The second electrode 144 may include, for example, at least one of chromium (Cr), gold (Au), aluminum (Al), cobalt (Co), copper (Cu), and nickel (Ni).

A plurality of plasmon nanoparticles 150 may be arranged on an upper surface of the top absorber 130. For example, the plurality of plasmon nanoparticles 150 may be arranged on a portion of the upper surface of the top absorber 130 that is not covered by the first electrode 142. In some embodiments, the plurality of plasmon nanoparticles 150 may be arranged entirely on the portion of the upper surface of the top absorber 130 that is not covered by the first electrode 142.

In some embodiments, the plurality of plasmon nanoparticles 150 may be in contact with the upper surface of the top absorber 130. In some embodiments, the plurality of plasmon nanoparticles 150 may be bonded to graphene in the top absorber 130. For example, the plurality of plasmon nanoparticles 150 may be bonded to graphene of the top absorber 130 in a plasmon bonding. By bonding the plurality of plasmon nanoparticles 150 to the graphene in the top absorber 130, the Fermi level of the graphene may be changed. For example, the Fermi level of the graphene may be lowered by the bonding described above. As the Fermi level of graphene decreases, a width of the depletion region may increase when the pn diode of the two-dimensional material layer 120 and the semiconductor substrate 110 is formed.

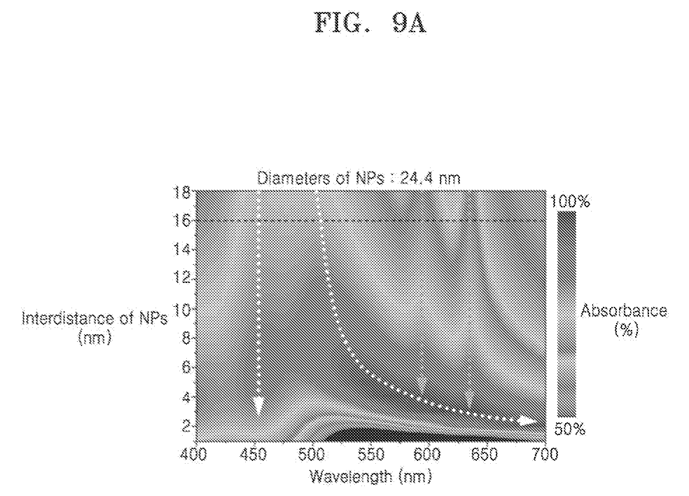

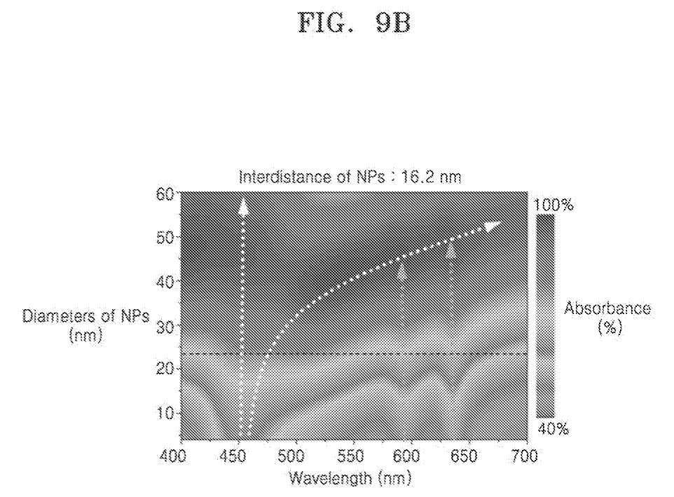

In some embodiments, the plurality of plasmon nanoparticles 150 may be arranged on the upper surface of the top absorber 130 at the same separation distance NPI, respectively. In some embodiments, the separation distance NPI may be in a range of about 4 nm to about 10 nm. As described below with reference to FIGS. 9A and 9B, the absorption rate of incident light having the same wavelength may vary depending on the separation distance NPI between the plurality of plasmon nanoparticles 150.

In some embodiments, each of the plurality of plasmon nanoparticles 150 may have a diameter NPD of about 20 nm to about 60 nm. As described below with reference to FIGS. 9A and 9B, the absorption rate of incident light having the same wavelength may be changed depending on the diameter NPD of each of the plurality of plasmon nanoparticles 150. In some embodiments, the plurality of plasmon nanoparticles may include at least one material selected from the group consisting of gold (Au), silver (Ag), aluminum (Al), tungsten oxide (WO₃), indium tin oxide (ITO), aluminum-doped zinc oxide (AZO), and cesium-doped indium oxide (ICO).

The image sensor 100 according to embodiments may include a plurality of plasmon nanoparticles 150 arranged on the upper surface of the top absorber 130 and bonded to graphene in the top absorber 130. Accordingly, due to the plasmon effect, the absorption rate of incident light entering the image sensor 100 increases, and the probability of carrier multiplication by excited electrons in the top absorber 130 may increase. In addition, hot electrons, which are generated from a plurality of plasmon nanoparticles 150 by incident light incident on the image sensor 100, may move to the top absorber 130 through tunneling, to thereby increase the amount of photocurrent.

An image sensor 100 according to other embodiments may further include additional elements, such as a floating diffusion region for accumulating electrons collected from the hybrid photodiode HPD, a pixel transistor for applying a voltage to the hybrid photodiode HPD, a pixel device isolation layer for separating the semiconductor substrate 110 into a plurality of pixel regions, an RGB color filter corresponding to each pixel region, a microlens for concentrating incident light into each pixel region, etc.

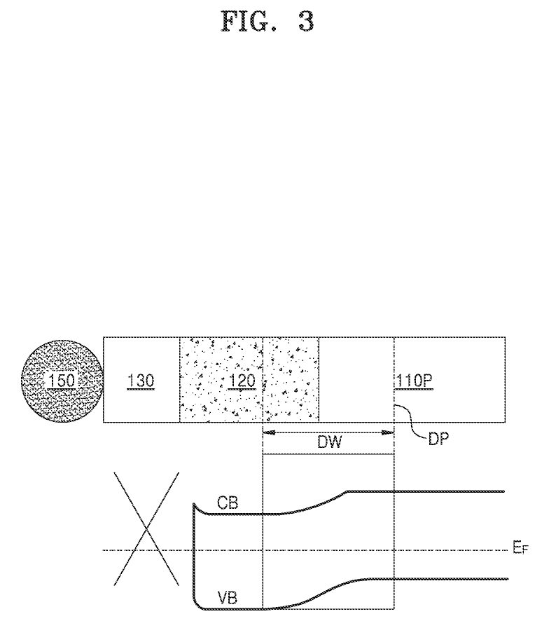

FIG. 3 is a schematic view illustrating a schematic energy band structure of an image sensor 100 according to embodiments. In FIG. 3, a schematic energy band structure of the hybrid photodiode HPD and the top absorber 130 arranged thereon in the image sensor 100 in FIG. 1 is shown.

Referring to FIG. 3, the hybrid photodiode HPD composed of a three-dimensional p-type silicon substrate (i.e., a doped region 110P) and an n-type two-dimensional material layer 120 may make an energy band to bend in the junction area.

The depletion region DP may be formed in the junction area between the three-dimensional p-type silicon substrate (i.e., the doped region 110P) and the n-type two-dimensional material layer 120, and an electric field may be generated in the depletion region DP. Since the n-type two-dimensional material layer 120 is formed to have the first thickness t1, which is relatively small, shown in FIG. 1, a width DW of the depletion region DP may also become relatively small, and thus, a significantly large electric field may be generated in the depletion region DP due to a spatial limitation. Accordingly, the electron-hole pairs may be more rapidly separated in the depletion region DP.

The top absorber 130 including the monolayer of graphene may have an energy band structure in which two cones meet at a vertex (e.g., Dirac point). When a single photon is excited in the top absorber 130, the excited electrons may have high kinetic energy and induce carrier multiplication. Accordingly, when a single photon is excited, two electron carriers may be generated from the single photon.

The Fermi level of the top absorber 130 including the monolayer of graphene may be lowered by the plasmon bonding between graphene of the top absorber 130 and a plurality of plasmon nanoparticles 150. Accordingly, as compared with the case where no plasmon nanoparticles 150 are arranged on the upper surface of the top absorber 130, the doping degree of the n-type impurities may be reduced in the n-type two-dimensional material layer 120, and thus, the width DW of the depletion region DP may relatively increase in the junction area of the p-type three-dimensional silicon substrate (i.e., doped region 110P) and the n-type two-dimensional material layer 120. Accordingly, the absorption rate of incident light may increase in the image sensor 100 shown in FIGS. 1 and 2.

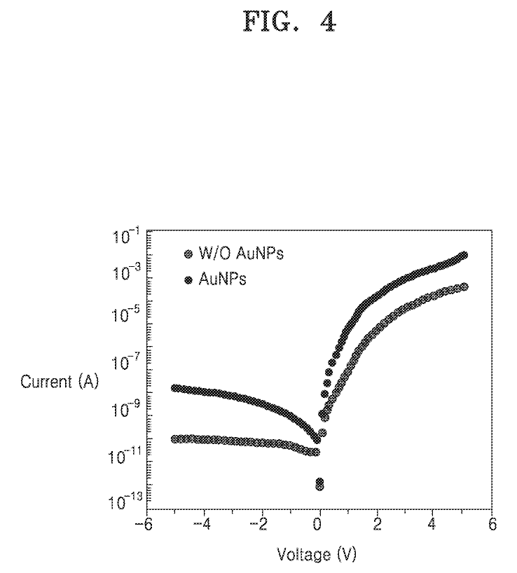

FIG. 4 is a graph showing a voltage-current behavior of an image sensor according to embodiments. For example, FIG. 4 is a graph showing the voltage-current behavior when a plurality of plasmon nanoparticles 150 are arranged on the top absorber 130 and when no plasmon nanoparticles 150 are arranged on the top absorber 130.

Referring to FIG. 4, in both of a voltage range having positive values and a voltage range having negative values, a relatively larger current is obtained when a plurality of plasmon nanoparticles 150 are arranged on the upper surface of the top absorber 130 than when no plasmon nanoparticles 150 are arranged on the upper surface of the top absorber 130. As described above, the Fermi level of the top absorber 130 may be lowered due to the bonding of a plurality of plasmon nanoparticles 150 and the top absorber 130, and as a result, the width of the depletion region increases when forming the pn diode of the semiconductor substrate 110 and the two-dimensional material layer 120. Accordingly, the image sensor 100 shown in FIGS. 1 and 2 may have improved diode rectification characteristics as compared with the image sensor that does not include a plurality of plasmon nanoparticles 150.

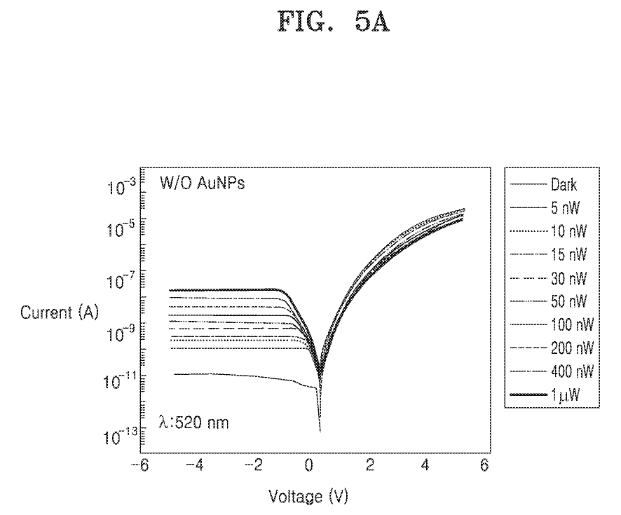

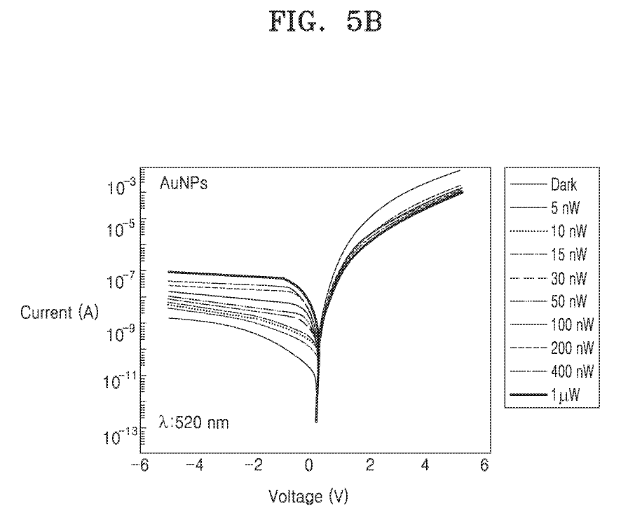

FIGS. 5A and 5B are graphs showing a voltage-optical current behavior of an image sensor according to embodiments. For example, FIGS. 5A and 5B are graphs showing the voltage-photoelectric current behavior when no plasmon nanoparticles 150 are arranged on the upper surface of the top absorber 130 (graph a) and when a plurality of plasmon nanoparticles 150 are arranged on the upper surface of the top absorber 130 (graph b), and shows that the voltage-photoelectric current curve according to the power of the incident light when incident light having 520 nm wavelength is incident on the image sensor.

Referring to FIGS. 5A and 5B, when a plurality of plasmon nanoparticles 150 are arranged on the upper surface of the top absorber 130 (graph b), the photoelectric current is confirmed to sequentially increase in a voltage range of negative values as the power of the incident light incident on the image sensor increases. For example, the image sensor 100 shows reliable photoelectric conversion characteristics even at a relatively low operating voltage.

In addition, when a plurality of plasmon nanoparticles 150 are arranged on the upper surface of the top absorber 130 (graph b), the photocurrent is confirmed to be greater in the voltage range of negative values as compared with the case where no plasmon nanoparticles 150 are arranged on the upper surface of the top absorber 130.

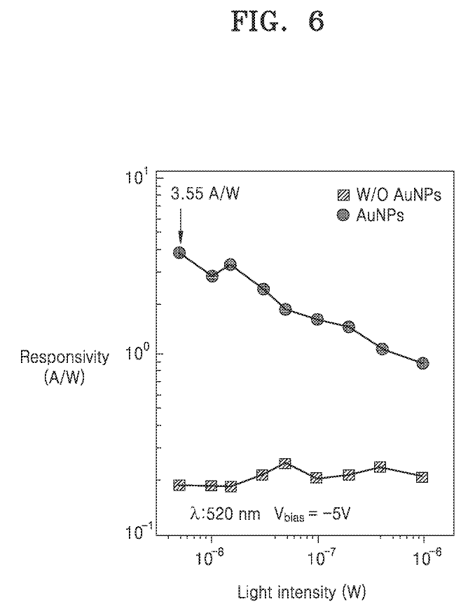

FIG. 6 is a graph showing responsivity according to the power of the incident light of an image sensor according to embodiments. For example, FIG. 6 is a graph showing the responsivity according to the power of the incident light when a plurality of plasmon nanoparticles 150 are arranged on the upper surface of the top absorber 130 and when no plasmon nanoparticles 150 are arranged on the top absorber 130, and shows the responsivity curve when incident light having 520 nm wavelength is incident on the image sensor under a reverse bias voltage of about -5 V.

Referring to FIG. 6, when a plurality of plasmon nanoparticles 150 are arranged on the upper surface of the top absorber 130, the responsivity is relatively higher in an entire power range of the incident light shown in FIG. 6 as compared with the case where no plasmon nanoparticles 150 are arranged on the upper surface of the top absorber 130.

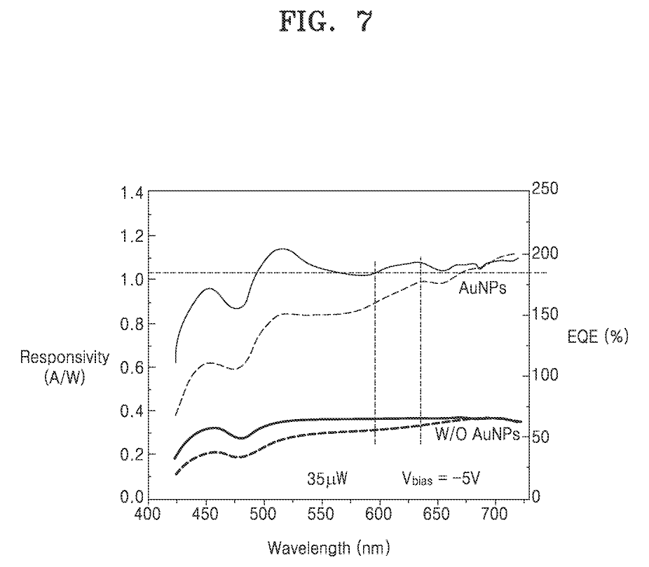

FIG. 7 is a graph showing responsivity and quantum efficiency according to the wavelength of the incident light of an image sensor according to embodiments. Specifically, FIG. 7 is a graph showing the responsivity and the quantum efficiency according to a wavelength of the incident light when a plurality of plasmon nanoparticles 150 are arranged on the upper surface of the top absorber 130 (graph of AuNPs) and when no plasmon nanoparticles 150 are arranged on the top absorber 130 (graph of W/O AuNPs) when about 35 μW of power of the incident light is applied to the image sensor under a reverse bias voltage of about -5 V.

Referring to FIG. 7, when a plurality of plasmon nanoparticles 150 are arranged on the upper surface of the top absorber 130, the responsivity is relatively higher in an entire wavelength range (from about 425 nm to about 750 nm) of the incident light shown in FIG. 7 as compared with the case where no plasmon nanoparticles 150 are arranged on the upper surface of the top absorber 130.

In addition, when a plurality of plasmon nanoparticles 150 are arranged on the upper surface of the top absorber 130, the quantum efficiency is confirmed to be relatively higher in the entire wavelength range (from about 425 nm to about 750 nm) of the incident light shown in FIG. 7 as compared with the case where no plasmon nanoparticles 150 are arranged on the upper surface of the top absorber 130.

As described above, the absorption rate of incident light incident on the image sensor 100 may increase due to the plasmon effect of a plurality of plasmon nanoparticles 150, the probability of carrier multiplication caused by electrons excited by the top absorber 130 may be increased, and the hot electrons generated from the plurality of plasmon nanoparticles 150 by incident light may move to the top absorber 130 through tunneling.

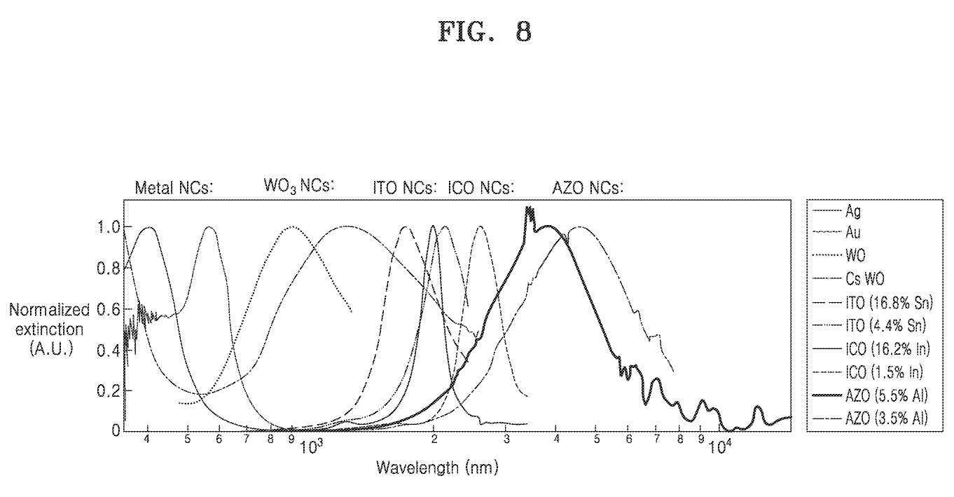

FIG. 8 is a graph showing an absorption degree of incident light according to the type of plasmon nanoparticles in the image sensor 100 according to embodiments.

Referring to FIG. 8, when a plurality of plasmon nanoparticles 150 are made of metal nanoparticles such as gold (Au) and silver (Ag), incident light having a relatively small wavelength (for example, visible ray and near-infrared ray) may be absorbed, and when a plurality of plasmon nanoparticles 150 include oxides such as tungsten oxide (WO3), indium tin oxide (ITO), zinc oxide doped with aluminum, and indium oxide doped with cesium, incident light having a relatively large wavelength (for example, far-infrared ray) may be absorbed. For example, the image sensor 100 may absorb incident light having various wavelengths by changing materials of a plurality of plasmon nanoparticles 150 in the image sensor 100.

FIGS. 9A and 9B are graphs showing an absorption degree of incident light according to a diameter of the nanoparticle and a separation distance between nanoparticles in the image sensor 100 according to embodiments. For example, the graph in FIG. 9A shows the absorption degree of incident light according to the wavelength of incident light and the separation distance between the plurality of plasmon nanoparticles 150 when the diameter of each plasmon nanoparticle 150 is about 24.4 nm, and the graph in FIG. 9B shows the absorption degree of incident light according to the wavelength of incident light and the diameter of each plasmon nanoparticle 150 when the separation distance between the plurality of plasmon nanoparticles 150 is about 16.2 nm.

Referring to FIGS. 9A and 9B, the separation distances between the plurality of plasmon nanoparticles 150 for which the absorption rate of incident light is relatively high are confirmed to be different according to the wavelength of incident light. In addition, in the entire wavelength range of incident light (from about 400 nm to about 700 nm) shown in FIGS. 9A and 9B, the absorption rate of the incident light is confirmed to be relatively high when the separation distance is about 2 nm to about 14 nm.

In addition, the diameters of each plasmon nanoparticle 150 for which the absorption rate of incident light is relatively high are confirmed to be different according to the wavelength of incident light. In addition, in the entire wavelength range of incident light (from about 400 nm to about 700 nm) shown in FIGS. 9A and 9B, the absorption rate of the incident light is confirmed to be relatively high when the diameter is about 20 nm to about 60 nm.

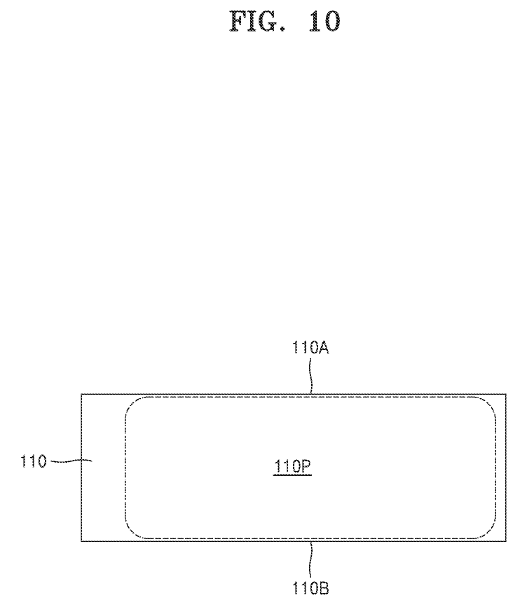

FIGS. 10 to 12 are cross-sectional views illustrating a method of manufacturing an image sensor 100 according to embodiments.

Referring to FIG. 10, a semiconductor substrate 110 may be provided. The semiconductor substrate 110 may include the upper surface 110A and the lower surface 110B. Thereafter, p-type impurities may be implanted onto the semiconductor substrate 110 to form the doped region 110P. The doped region 110P may be a region doped with p-type impurities such as boron or gallium.

The semiconductor substrate 110 may be grinded off before the doped region 110P is formed to thereby reduce a thickness thereof, or a portion of the semiconductor substrate 110 may be grinded off from the lower surface 110B after impurities are implanted onto the upper surface 110A of the semiconductor substrate 110 to form the doped region 110P, to thereby reduce the thickness thereof. A support substrate may be attached to the lower surface 110B of the semiconductor substrate 110.

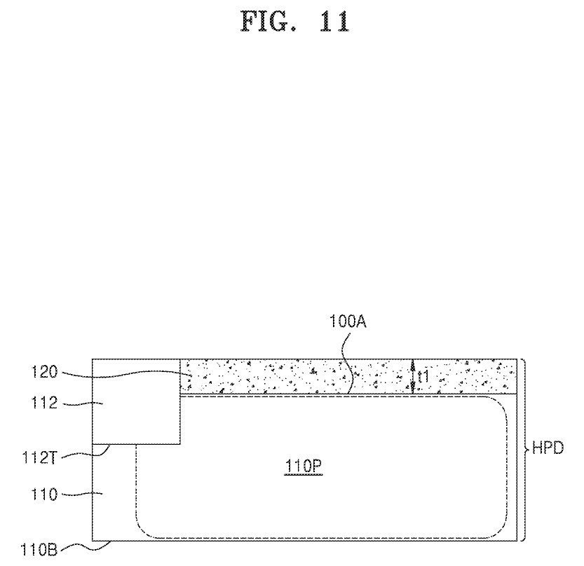

Referring to FIG. 11, the two-dimensional material layer 120 may be formed on the upper surface 110A of the semiconductor substrate 110.

In some embodiments, the two-dimensional material layer 120 may include molybdenum disulfide (MoS₂), and may be formed by a chemical vapor deposition process such as a metal organic chemical vapor deposition process. In some embodiments, the two-dimensional material layer 120 may be formed by using a first precursor including molybdenum and a second precursor including sulfur. In some embodiments, the first precursor may include at least one of molybdenum (Mo), molybdenum trioxide (MoO₃), molybdenum hexafluoride (MoF₆), molybdenum chloride (MoCl₆), and molybdenum hexacarbonyl (Mo(CO)₆). The process of forming the two-dimensional material layer 120 may be performed at a temperature of, for example, about 300°C to about 700°C. However, embodiments are not limited thereto.

In some embodiments, the two-dimensional material layer 120 may be composed of two-dimensional sheets of two to five layers and have a first thickness t1 of about 1.5 nm to about 3.5 nm in a vertical direction.

In other embodiments, the two-dimensional material layer 120 may be formed by an atomic layer deposition process or an evaporation process.

After forming the two-dimensional material layer 120, a mask pattern may be formed on the two-dimensional material layer 120 and the semiconductor substrate 110, and then, portions of the two-dimensional material layer 120 and the semiconductor substrate 110 may be removed by using the mask pattern as an etching mask, to thereby form the device isolation trench 112T, and an insulation material may be filled into the device isolation trench 112T to thereby form the device isolation layer 112.

However, embodiments are not limited thereto, and the device isolation layer 112 may be formed first on the semiconductor substrate 110 prior to the two-dimensional material layer 120, and the two-dimensional material layer 120 may be formed on the semiconductor substrate 110 and the device isolation layer 112.

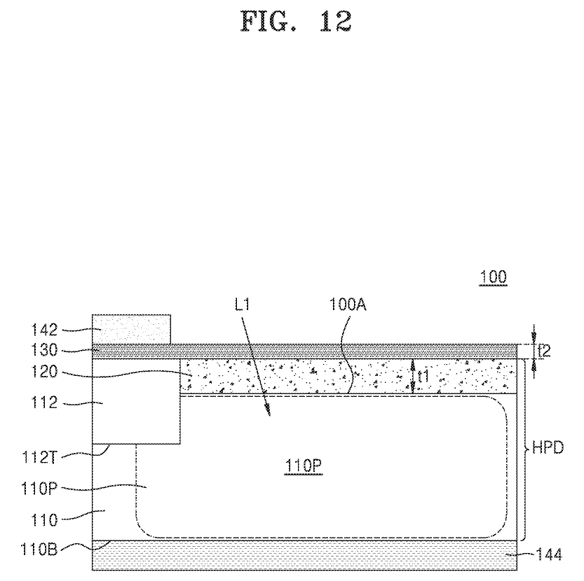

Referring to FIG. 12, in the result of process described in detail with reference to FIG. 11, the top absorber 130 may be formed on the two-dimensional material layer 120. In some embodiments, the top absorber 130 may include the monolayer of graphene.

For example, the top absorber 130 may be formed by a chemical vapor deposition process. The chemical vapor deposition process may include any one of a low-pressure chemical vapor deposition (LPCVD) process, an atmospheric pressure chemical vapor deposition (APCVD) process, and a plasma enhanced chemical vapor deposition (PECVD) process. The chemical vapor deposition process may be performed at a temperature of about 800°C to about 1100°C using a hydrocarbon-based precursor such as methane, benzene, toluene, pyridine, naphthalene, etc.

After forming the top absorber 130, the first electrode 142 may be formed on the upper surface of the top absorber 130. In some embodiments, the first electrode 142 may be formed on a portion of the top absorber 130 that is arranged on the upper surface of the device isolation layer 112. For example, the first electrode 142 may be formed at a position vertically overlapping the device isolation layer 112. The first electrode 142 may be formed of at least one of chromium (Cr), gold (Au), aluminum (Al), cobalt (Co), copper (Cu), and nickel (Ni).

After forming the first electrode 142, a plurality of plasmon nanoparticles 150 may be formed on the upper surface of the top absorber 130 that is exposed without being covered by the first electrode 142. In some embodiments, the plurality of plasmon nanoparticles 150 may be formed to be uniformly arranged on the upper surface of the top absorber 130. For example, the plurality of plasmon nanoparticles 150 may be arranged on the upper surface of the top absorber 130 in a matrix arrangement.

For example, a mask pattern covering the first electrode 142 may be formed on the top absorber 130, a solution in which a plurality of plasmon nanoparticles 150 are dispersed may be coated on the top absorber 130 on which the mask pattern is formed by a spin coating process, and the solution may be dried, to thereby form the plurality of plasmon nanoparticles 150 on the top absorber 130.

Next, in the result of process described in detail with reference to FIG. 12, the semiconductor substrate 110 may be turned over and the lower surface 110B of the semiconductor substrate 110 may face upward, and then, the second electrode 144 may be formed on the lower surface 110B of the semiconductor substrate 110. In some embodiments, the second electrode 144 may be formed of at least one of chromium (Cr), gold (Au), aluminum (Al), cobalt (Co), copper (Cu), and nickel (Ni). As the second electrode 144 is formed, the image sensor 100 shown in FIGS. 1 and 2 may be manufactured.

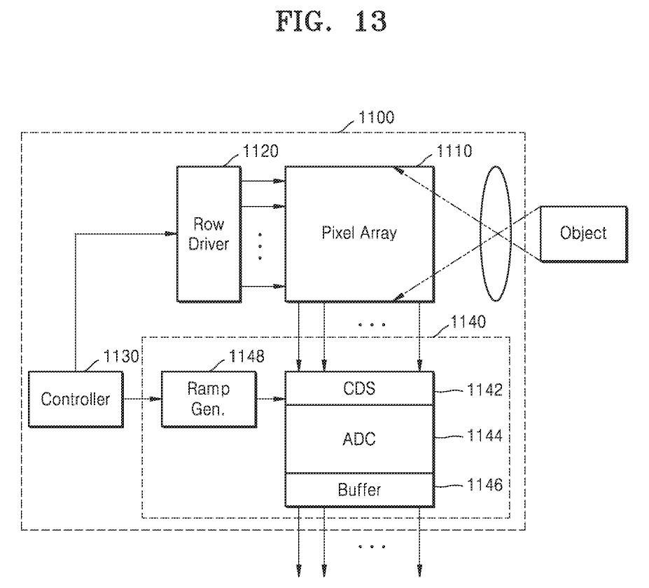

FIG. 13 is a block diagram showing a configuration of an image sensor 1100 according to embodiments.

Referring to FIG. 13, an image sensor 1100 according to embodiments may include a pixel array 1110, a controller 1130, a row driver 1120, and a pixel signal processing unit 1140. The image sensor 1100 may include the image sensor 100 described above.

The pixel array 1110 may include a plurality of unit pixels that are arranged two-dimensionally, and each unit pixel may include a photoelectric conversion device. The photoelectric conversion device may absorb light and generate charges, and an electrical signal (output voltage) according to the generated charge may be provided to the pixel signal processing unit 1140 by a vertical signal line. The unit pixels in the same row of the pixel array 1110 may provide a single output voltage at a time row by row, and thus, the unit pixels in the same row of the pixel array 1110 may be simultaneously activated by a selection signal output from the row driver 1120. The unit pixels in the selected row may provide the output voltage depending on the absorbed light in the photoelectric conversion device to an output line of a corresponding column of the pixel array 1110.

The controller 1130 may control the pixel array 1110 to absorb light and to accumulate charges, control the accumulated charges to be temporarily stored, and control the row driver 1120 to output the electrical signal corresponding to stored charges to the outside of the pixel array 1110. In addition, the controller 1130 may control the pixel signal processing unit 1140 to detect the output voltage provided by the pixel array 1110.

The pixel signal processing unit 1140 may include a correlation double sampler (CDS) 1142, an analog-to-digital converter (ADC) 1144, and a buffer 1146. The correlation double sampler 1142 may perform sampling and holding of the output voltage provided by the pixel array 1110. The correlation double sampler 1142 may take a specific noise level and an output level according to the generated output voltage, and output a difference level corresponding to the difference between the noise level and the output level. In addition, the correlation double sampler 1142 may receive a lamp signal generated from a lamp signal generator 1148, compare the lamp signal with one of the noise level and the output level, and output the comparison result.

The analog-to-digital converter 1144 may convert an analog signal, which corresponds to the difference level received from the correlation double sampler 1142, into a digital signal. The buffer 1146 may latch the digital signal, and the latched signal may be sequentially output to the outside of the image sensor 1100 and be transmitted to an image processor.

Embodiments are disclosed in the drawings and specification as described above. Although embodiments have been described using specific terms in the specification, the terms are used only for the purpose of describing the embodiments and are not used to limit the scope. Therefore, those of ordinary skill in the art will understand that various modifications and equal other embodiments are possible from this.

While embodiments have been described with reference to the figures, it will be understood by those of ordinary skill in the art that various changes in form and details may be made therein without departing from the spirit and scope as defined by the following claims and their equivalents.

What is claimed is:

1. An image sensor comprising:
a semiconductor substrate;
a two-dimensional material layer on an upper surface of the semiconductor substrate and comprising molybdenum disulfide (MoS₂); and
a top absorber on an upper surface of the two-dimensional material layer and comprising graphene; and
a plurality of plasmon nanoparticles on an upper surface of the top absorber,
wherein the semiconductor substrate comprises silicon doped with p-type impurities and the two-dimensional material layer has an n-type conductivity, the two-dimensional material layer and the semiconductor substrate forming a pn diode.

2. The image sensor of claim 1, wherein each of the plurality of plasmon nanoparticles contacts the upper surface of the top absorber.

3. The image sensor of claim 1, wherein each of the plurality of plasmon nanoparticles contacts the graphene included in the top absorber and is configured to change a Fermi level of the graphene.

4. The image sensor of claim 1, wherein each of the plurality of plasmon nanoparticles comprises at least one of gold (Au), silver (Ag), aluminum (Al), tungsten oxide (WO₃), indium tin oxide (ITO), aluminum-doped zinc oxide (AZO), and cesium-doped indium oxide (ICO).

5. The image sensor of claim 1, wherein each of the plurality of plasmon nanoparticles has a diameter in a range of 20 nm to 60 nm.

6. The image sensor of claim 1, wherein the plurality of plasmon nanoparticles are on the upper surface of the top absorber,
wherein a separation distance between adjacent plasmon nanoparticles among the plurality of plasmon nanoparticles is constant, and
wherein the separation distance between the plurality of plasmon nanoparticles is in a range of 4 nm to 14 nm.

7. The image sensor of claim 1, wherein the plurality of plasmon nanoparticles are on the upper surface of the top absorber and on an entire area of the upper surface of the top absorber.

8. The image sensor of claim 1, wherein the plurality of plasmon nanoparticles are in a monolayer.

9. The image sensor of claim 1, wherein a quantum efficiency of the image sensor is greater than 100%.

10. The image sensor of claim 1, further comprising:
a first electrode on the top absorber such that the first electrode is spaced apart from the plurality of plasmon particles and electrically connected to the two-dimensional material layer; and
a second electrode electrically connected to the semiconductor substrate.

11. An image sensor comprising:
a semiconductor substrate;
a two-dimensional material layer on an upper surface of the semiconductor substrate and comprising molybdenum disulfide (MoS2), the two-dimensional material layer comprising two to five two-dimensional sheets on the upper surface of the semiconductor substrate in a vertical direction; and
a top absorber on an upper surface of the two-dimensional material layer and comprising a monolayer of graphene,
wherein a plurality of plasmon nanoparticles are on an upper surface of the top absorber.

12. The image sensor of claim 11, wherein the plurality of plasmon nanoparticles contact the upper surface of the top absorber and contact the monolayer of graphene of the top absorber, and
wherein the plurality of plasmon nanoparticles are configured to change a Fermi level of the monolayer of graphene.

13. The image sensor of claim 11, wherein the plurality of plasmon nanoparticles comprise at least one of gold (Au), silver (Ag), aluminum (Al), tungsten oxide (WO₃), indium tin oxide (ITO), aluminum-doped zinc oxide (AZO), and cesium-doped indium oxide (ICO).

14. The image sensor of claim 11, wherein the image sensor has a quantum efficiency greater than 100%.

15. The image sensor of claim 11, wherein the semiconductor substrate comprises silicon doped with p-type impurities, and
wherein the two-dimensional material layer has an n-type conductivity, and
wherein the semiconductor substrate and the two-dimensional material layer form a pn diode.

16. The image sensor of claim 11, further comprising:
a first electrode on the top absorber such that the first electrode is spaced apart from the plurality of plasmon particles and electrically connected to the two-dimensional material layer; and
a second electrode electrically connected to the semiconductor substrate.

17. An image sensor comprising:
a semiconductor substrate comprising a doped region doped with p-type impurities;
a two-dimensional material layer on an upper surface of the semiconductor substrate and comprising molybdenum disulfide (MoS2), the two-dimensional material layer comprising two to five two-dimensional sheets on the upper surface of the semiconductor substrate in a vertical direction;
a top absorber on an upper surface of the two-dimensional material layer and a monolayer of graphene;
a first electrode on the top absorber; and
a second electrode on a lower surface of the semiconductor substrate and electrically connected to the doped region,
wherein a plurality of plasmon nanoparticles are on an upper surface of the top absorber, and
wherein each of the plurality of plasmon nanoparticles contacts the monolayer of graphene of the top absorber based on a plasmon bonding.

18. The image sensor of claim 17, wherein each of the plurality of plasmon nanoparticles comprises at least one of gold (Au), aluminum (Al), and silver (Ag).

19. The image sensor of claim 17, further comprising
a device isolation layer in a device isolation trench extending from the upper surface of the semiconductor substrate into the semiconductor substrate,
wherein a portion of the top absorber is on the device isolation layer,
wherein the first electrode is on the portion of the top absorber overlapping the device isolation layer, and
wherein the plurality of plasmon nanoparticles are spaced apart from the first electrode on the upper surface of the top absorber.

20. The image sensor of claim 17, wherein, based on visible light being incident the plurality of plasmon nanoparticles, the plurality of plasmon nanoparticles are configured to generate hot electrons that move from the plurality of plasmon nanoparticles to the top absorber through tunneling.
